(19) United States
(12) Patent Application Publication
(10) Pub. No.: US 2011/0253442 A1
(43) Pub. Date: Oct. 20, 2011

(54) EMC Protection System and Tower with EMC Protection System

(76) Inventor: Bastian Lewke, Herning (DK)

(21) Appl. No.: 13/079,231

(22) Filed: Apr. 4, 2011

(30) Foreign Application Priority Data
Apr. 16, 2010 (EP) 10004078.1

(51) Int. Cl. H05K 9/00

(52) U.S. Cl. 174/377

(57) ABSTRACT

An electromagnetic compatibility protection system for electrical cables inside a tower with an internal down-conductor is disclosed. The electromagnetic compatibility protection has a U-shaped shield with a base portion and two adjoining side portions. The base portion and the side portions define a protected space for the electrical cables. A tower with the electromagnetic compatibility protection system is also disclosed.

### CROSS REFERENCE TO RELATED APPLICATIONS

This application claims priority of European Patent Office application No. 10004078.1 EP filed Apr. 16, 2010, which is incorporated by reference herein in its entirety.

### FIELD OF INVENTION

The invention relates to an electromagnetic compatibility (EMC) protection system and more particularly to EMC protection for electrical cables inside of a tower.

### BACKGROUND OF INVENTION

Towers like for example towers of wind turbines are subjected to strikes of lightning which induce lightning current into the tower and/or structures mounted onto the towers. Often, especially for wind turbine steel towers are used. The lightning current flows through the tower to the ground. Electrical cables running inside the tower are protected against electromagnetic fields by the Faraday cage of the steel tower.

Towers made of concrete or having a lattice structure do not provide the Faraday cage and therefore not the same shielding against electromagnetic fields. A lightning current is conducted by one or more down-conductors to the ground. The down-conductors are arranged inside the tower. The electromagnetic field resulting from the flowing lightning current induces high voltages and currents in the electrical cables running inside the tower. The induced currents can damage or destroy electric or electronic systems which are connected to the cables. This problem is even more severe for high towers like example wind turbine towers with a height of 100 meters as the electrical cables form very long loops.

U-shaped shields for shielding the magnetic field mitigation from underground power cables are known from the article “Parametric analysis of magnetic field mitigation shielding for underground power cables”, J. C. del Pino Lopez, P. Cruz Romero and P. Dular, Department of Electrical Engineering, University of Seville. The article shows how effective the shielding in the underground protects the surrounding from magnetic fields.

### SUMMARY OF INVENTION

It is an object of the invention to provide EMC protection for towers without inherent EMC shielding capabilities.

This object is solved according to the features of the independent claims.

In one aspect the invention is directed to an EMC protection system for electrical cables inside a tower with an internal down-conductor. The EMC protection system comprises a U-shaped shield with a base portion and two adjoining side portions. The base portion and the side portions define a protected space for the electrical cables. The U-shaped shield offers electromagnetic and magnetic shielding in case of a lightning strike. As the shield does not completely envelop the electrical cables these can be accessed at all time and at all locations e.g. for maintenance. Further, the U-shaped EMC protection shield allows for an easy retrofitting of additional cables to the tower.

The shield may have a length of approximately the height of the tower. This ensures good protection for the electrical cables. The length of the shield may be greater than the height of the tower so that no electromagnetic fields are induced into the cables at the upper and/or lower end of the shield.

The protected space may not be influenced from surrounding electromagnetic fields. The flux lines of the electromagnetic field reach into the U-shaped shield to a certain extent. The area of the U-shaped shield which is free or almost free from the electromagnetic fields is the protected space in which the cables are arranged. The term almost free depends on the actual implementation of the EMC protection system. It means that the electromagnetic fields reaching into the protected space are under a certain threshold which guarantees that no damage occurs to connected systems.

Each side portion of the shield may have a length of at least the length of the base portion of the shield. Preferably, each side portion is higher than the length of the base portion. Both dimensionings ensure a safe distance from the cables to the surrounding electromagnetic fields.

Each side portion of the shield may have a length of at least one and a half times, preferably five to ten times of the thickness of the electrical cables arranged at the base portion. Here, the length of the side portions is significantly larger than the total thickness or height of the layer or layers of cables inside the U-shaped shield. The length of the side portions may also depend on the length of the base portion i.e. how open the U-shaped form is towards the surrounding.

The shield may comprise Al, Cu, Ferrite and/or steel. Other suitable shielding materials may also be used. These materials offer good EMC protection.

The shield may comprise longitudinal sections. The lengths of the side portions of the shield may be different for the longitudinal sections. This allows for a gradual or incremental adaptation of the level of EMC protection over the length of the shield. An adjustment to different protection requirements in different areas, parts or sub-assemblies is possible. For example, if some sections of electrical cables or their surroundings having different EMC characteristics need to be brought to a common EMC protection level the longitudinal sections of the shield will be useful.

In a further aspect the invention is directed to a tower with an EMC protection system. The tower has internal electrical cables and an internal down-conductor and comprises an EMC protection system as described in the foregoing. A tower with one or more internal down-conductors has an internal electromagnetic field in case of a strike of lightning resulting from the lightning current running through the down-conductor. The EMC protection system shields the electrical cables inside the tower from the electromagnetic or magnetic fields. Electrical or electronic systems in connection with the electrical cables are saved from damage or destruction by the EMC protection system. The EMC protection system offers towers without inherent protection like for example a Faraday cage of a steel tower a good EMC protection of internal electrical cables.

The tower may comprise concrete and/or a lattice structure. Concrete or lattice structures are easy and inexpensive to build while being robust at the same time.

The tower may carry or be a wind turbine. Wind turbines often have high towers reaching 100 meters or more. On top of the tower a nacelle is attached which surrounds the electric generator and further electric and electronic equipment. A main shaft carrying a blade hub is also located inside the nacelle. Because of the height and the rotating blades wind turbines are regularly hit by strikes of lightning. Inside the tower of a wind turbine several long cables reach from the ground to the top of the wind turbine which are vulnerable to electromagnetic fields. Further, the wind turbine comprises several sensitive and expensive electric and electronic systems.

The shield of the EMC protection system may also be arranged in a nacelle and/or a hub or further parts of the wind turbine. Preferably, the shield is used in wind turbine components lacking good EMC shielding like non-metallic parts. This allows for EMC protection of the complete wind turbine.

The shield may comprise longitudinal sections with different lengths of the side portions. The longitudinal sections may be assigned to different parts of the wind turbine like the tower, the nacelle or the hub. The different parts of the wind turbine have different electromagnetic characteristics which can be adjusted by the longitudinal sections of the shield to a common level of EMC protection.

### BRIEF DESCRIPTION OF THE DRAWINGS

The accompanying drawings are included to provide a further understanding of embodiments. Other embodiments and many of the intended advantages will be readily appreciated as they become better understood by reference to the following detailed description. The elements of the drawings do not necessarily scale to each other. Like reference numbers designate corresponding similar parts.

FIG. 1 illustrates a schematic view of a tower equipped with an EMC protection system according to the invention.

FIG. 2 illustrates a schematic view of an EMC protection system according to a first embodiment of the invention.

FIG. 3 illustrates a schematic view of an EMC protection system according to a second embodiment of the invention.

### DETAILED DESCRIPTION OF INVENTION

In the following detailed description, reference is made to the accompanying drawings which faun a part hereof and in which are shown by way of illustration specific embodiments in which the invention may be practised. In this regard, directional terminology, such as “top” or “bottom” etc. is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

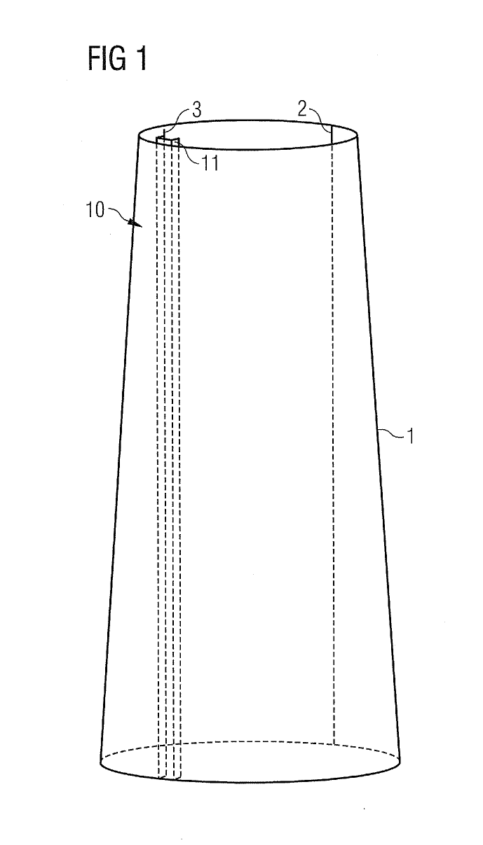

FIG. 1 shows a tower 1 made of concrete. The tower may use a lattice or girder structure or a combination of concrete and lattice structure. The tower 1 can be used as a platform for a wind turbine or for telecommunication installations, for example. The tower 1 can reach a height of 100 meters and more. As the tower 1 has a concrete shell it offers no electromagnetic shielding capabilities like a Faraday cage of a steel tower. Therefore, the tower 1 comprises one or more internal down-conductors 2 to conduct current from lightning strikes to the ground.

One or more electrical cables 3 run from the top of the tower 1 to the bottom. The electrical cables 3 convey energy and signals. In case of a wind turbine energy is conveyed in both directions. In case of a strike of lightning to the installations on top of the tower 1 the lightning current is guided by the down-conductor 2 through the tower 1 to the ground. The resulting electromagnetic fields induce high voltages and currents in the electrical cables 3 which could damage or destroy electric and electronic equipment connected with the electrical cables 3.

An electromagnetic compatibility (EMC) protection system 10 is installed in the tower 1 to secure the electrical cables 3 from electromagnetic fields. The EMC protection system 11 has a shield 11 which reaches from the top of the tower 1 to the bottom. The shield 11 can be longer than the height of the tower 1 to avoid induction of fields into the ends of the shield 11. At the bottom the shield 11 may reach into the ground and at the top the shield 11 may extend into an adjacent part.

In case of a wind turbine the shield 11 or a part of the shield 11 may extend into a nacelle arranged on top of the tower 1 and/or even further into a hub carrying the blades.

The shield 11 or parts of the shield 11 may have longitudinal sections with different EMC protection capabilities. This allows for a fine adaptation of the shield 11 to specific EMC protection requirements which vary over the length of the shield 11. Varying EMC protection requirements can occur, for example in different parts of a tower or a wind turbine like tower and nacelle and/or hub. With the help of the longitudinal sections it is possible to set up a common level of EMC protection for different surroundings in a tower, wind turbine or other device.

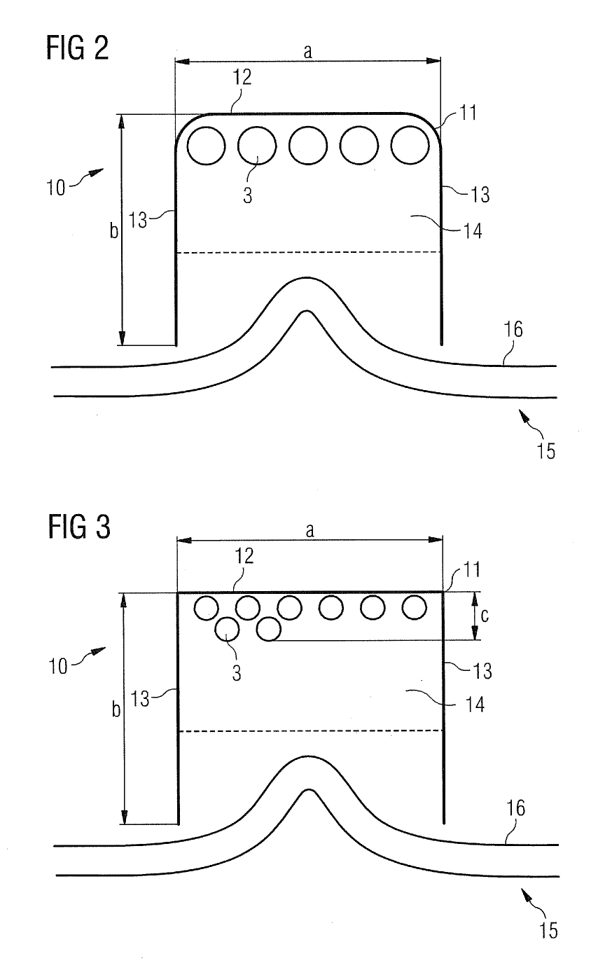

The shield surrounds the electrical cables 3 partially. FIGS. 2 and 3 show the shield 11 in greater detail.

FIG. 2 shows a schematic cross-section of the shield 11 of the EMC protection system 10. The shield 10 has a base portion 12 at which the electrical cables 3 are arranged. The base portion 12 has a length a. At ends of the base portion 12 in longitudinal direction two side portions 13 are arranged. The side portions 13 are substantially parallel. The side portions 13 are integrally formed with base portion 12. It is also possible to mount the base portion 12 and two side portions 13 together to form a shield 11. The shield 11 consists of aluminium, copper, ferrite, steel, other suitable shielding materials or a combination of one or more of these materials.

The base portion 12 and the side portions 13 have a U-shaped form and define an open space in which the electrical cables 3 are arranged. One part of the open space is a protected space 14. The protected space 14 begins at the base portion 12 and stretches along the length of the side portions 13. The end of the protected space 14 is defined on the basis of electromagnetic or magnetic fields 15 reaching into the open space of the shield 11.

Flux lines 16 of the electromagnetic field reach into the open space of the shield 11 as shown in the Figure. The protected space 14 can be defined as the space inside the U-shaped opening of the shield 11 which is free from flux lines 16 of electromagnetic or magnetic fields 15. Another definition is that the protected space 14 is free from electromagnetic or magnetic fields 15 which exceed a certain threshold. In this case electromagnetic or magnetic fields 15 are tolerated inside the protected space 14 if the strength of the field 15 inside the protected space 14 is so low that no damage or destruction can harm electric or electronic systems in communication with the electrical cables 3. In FIG. 2 the protected space 14 reaches from the base portion 12 to the dashed line running parallel to the base portion 12.

The size of the protected space 14 depends on the length b of the side portions 13. The longer the side portions 13 are the larger the protected space 14 is. The size of the protected space 14 depends further on the length a of the base portion 12 and the strength of the electromagnetic or magnetic field 15. For a given length a of the base portion 12 the variable to define the size of the protected space is the length b of the side portions 13.

In FIG. 2 the length b of each side portion 13 is at least the length a of the base portion 12. This allows for good EMC protection while having good access to the cables 3 at the same time.

The electrical cables 3 are arranged in the protected space 14 close to the base portion 12. The electrical cables can be attached to the base portion 12 by fasteners, clamps, clips or the like. The fasteners can be attached to the base portion 12 or integrally formed with it. The fasteners can also be attached to one or both side portions 13.

FIG. 3 shows another embodiment of the EMC protection shield 11 having a similar structure wherein the same reference numerals designate the same parts.

Here, the length b of each side portion 13 is at least one and a half times, preferably five to ten times the thickness c of the one or more electrical cables 3 arranged at the base portion 12 of the shield 11. This dimensioning rule is based upon the payload of the shield 11.

A combination of the dimensioning rules of FIGS. 2 and 3 is also possible. For example, one can use the length b of the side portion 13 resulting from the dimensioning rule which gives the greater length.

The shield 11 can have several longitudinal sections with different EMC shielding capabilities. The length a of the base portions 12 of different longitudinal sections stays ideally the same while the lengths b of the side portions 13 vary to realize different shielding capabilities. Not only the shielding capabilities can be variable but the dimensioning rules as well. FIG. 2 may show the cross-section of one longitudinal section and FIG. 3 may show the cross-section of another longitudinal section.

The edges between the base portion 12 and the side portion 13 can be rounded like depicted in FIG. 2 or angular as shown in FIG. 3. The form of the edge is more likely defined by the production process than by electrical considerations.

The EMC protection system 10 can be mounted into the tower 1 while the tower 1 is build or it can be retrofitted later. The shield 11 of the EMC protection system 10 is attached to an inner surface of the tower 1. For best protection of the electrical cables 3 a space is chosen inside the tower 1 where the electromagnetic or magnetic fields 15 from the down-conductor 2 are as weak as possible. After the shield 11 is fixed to the tower 1 the electrical cables are passed through the shield 11. The cables may be fixed inside the shield 11.

At the upper end of the tower 1 the shield 11 may reach into the next component like a nacelle in case of a wind turbine or the shield 11 ends at the upper end. Another shield or a further part of the shield may be connected to the upper end of the shield 11.

Inspection, repair or later retrofitting of cables can be achieved easily as the shield 11 has an open side. The cables 11 can be accessed without obstacles. The size of the protected space can be planned with reserves so that later on additional cables can be inserted into the protected space 14.

In case of a strike of lightning to the installation mounted on the tower 1 the lightning current is guided to the ground by the down-conductor 2. Inside the tower 1 electromagnetic and magnetic fields 15 are generated by the lightning current. The fields 15 hit the shield 11 where the flux lines 16 of the field 15 are bent as shown in FIGS. 2 and 3. The flux lines 16 do not enter the protected space 14 so that the electrical cables 3 are shielded. Depending on the characteristics of the system the EMC protection system 10 may be designed to allow entry of weak fields into the protected space 14. This may be easier to build and more inexpensive. The weak fields do not harm or destroy electric or electronic system being in communication with the electrical cables 3.

1.-13. (canceled)

14. An electromagnetic compatibility protection system for electrical cables inside a tower with an internal down-conductor, comprising:
a U-shaped shield with a base portion, and two adjoining side portions,
wherein the base portion and the side portions define a protected space for the electrical cables.

15. The electromagnetic compatibility protection according to claim 14, wherein the shield has a length of approximately the height of the tower.

16. The electromagnetic compatibility protection according to claim 14, wherein the protected space is not influenced from surrounding electromagnetic fields.

17. The electromagnetic compatibility protection according to claim 14, wherein each side portion has a length of at least a length of the base portion.

18. The electromagnetic compatibility protection according to claim 14, wherein each side portion has a length of at least one and a half times a thickness of the electrical cables arranged at the base portion.

19. The electromagnetic compatibility protection according to claim 18, wherein each side portion has a length of five times a thickness of the electrical cables arranged at the base portion.

20. The electromagnetic compatibility protection according to claim 18, wherein each side portion has a length of ten times a thickness of the electrical cables arranged at the base portion.

21. The electromagnetic compatibility protection according to claim 14, wherein the shield comprises Al, Cu, Ferrite and/or steel.

22. The electromagnetic compatibility protection according to claim 14, wherein the shield comprises longitudinal sections and wherein the lengths of the side portions are different for the longitudinal sections.

23. A tower with an electromagnetic compatibility protection system, comprising:
internal electrical cables; and
an internal down-conductor, comprising the electromagnetic compatibility protection system claim 14.

24. The tower with an electromagnetic compatibility protection system according to claim 23, wherein the tower comprises concrete.

25. The tower with an electromagnetic compatibility protection system according to claim 23, wherein the tower comprises a lattice structure.

26. The tower with an electromagnetic compatibility protection system according to claim 23, wherein the tower supports a wind turbine.

27. The tower with an electromagnetic compatibility protection system according to claim 26, wherein the shield is arranged in a nacelle and/or a hub of the wind turbine.

28. The tower with an electromagnetic compatibility protection system according to claim 27, wherein the shield comprises longitudinal sections with different lengths of the side portions and wherein the longitudinal sections are assigned to different parts of the wind turbine.
